(19) United States
(12) Patent Application Publication
(10) Pub. No.: US 2026/0343846 A1
(43) Pub. Date: Oct. 29, 2026

(54) WIRING PATTERNS OF INTEGRATED CIRCUITS

(71) Applicant: Samsung Electronics Co., Ltd., Suwon-si (KR)

(72) Inventors: Jimin Park, Suwon si (KR); Taehyung Kim, Suwon si (KR)

(21) Appl. No.: 19/431,560

(22) Filed: Dec. 23, 2025

(30) Foreign Application Priority Data
Apr. 23, 2025 (KR) 10-2025-0053349

(51) Int. Cl. H10B 10/00; G11C 11/418

(52) U.S. Cl. CPC H10B 10/18; G11C 11/418; H10B 10/125

(57) ABSTRACT

An integrated circuit includes a cell region in which bit cells are arranged and a peripheral region in which word line drivers including a first word line driver are arranged, wherein the cell region includes a first gate line extending in a first direction above a substrate, a first wiring pattern disposed in a front side wiring layer above the first gate line and electrically connected to the first gate line, a backside contact extending in the substrate in a vertical direction, and a backside wiring pattern on a backside of the substrate and electrically connected to the first wiring pattern through the backside contact, and the peripheral region includes a second wiring pattern in the front side wiring layer and directly connected to the first wiring pattern to transfer a first word line signal output from the first word line driver to the first wiring pattern.

### CROSS-REFERENCE TO RELATED APPLICATION

This application claims priority under 35 U.S.C. § 119 to Korean Patent Application No. 10-2025-0053349, filed on Apr. 23, 2025, in the Korean Intellectual Property Office, the entirety of which is incorporated by reference herein.

### BACKGROUND

Along with the demand for high integration and the development of a semiconductor process, the widths, intervals, and/or heights of wirings included in an integrated circuit may decrease, and an influence of a parasitic element of a wiring may increase. In addition, for reduced power consumption, a high operating speed, and the like, the power supply voltage of an integrated circuit may decrease, and accordingly, an influence of a parasitic element of a wiring, which affects the integrated circuit, may further increase. Therefore, the demand for an integrated circuit design method of efficiently routing wirings and vias has increased.

### SUMMARY

Some aspects of the present disclosure provide integrated circuits including bit cells, the integrated circuits providing reduced wiring resistance between a cell array and a peripheral circuit.

According to some implementations of the present disclosure, there is provided an integrated circuit including a cell region in which a plurality of bit cells are arranged and a peripheral region in which a plurality of word line drivers including a first word line driver are arranged, wherein the cell region includes a first gate line extending in a first direction above a substrate, a first wiring pattern disposed in a front side wiring layer above the first gate line and electrically connected to the first gate line, a backside contact extending in the substrate in a vertical direction, and a backside wiring pattern on a backside of the substrate and electrically connected to the first wiring pattern through the backside contact, and the peripheral region includes a second wiring pattern in the front side wiring layer and directly connected to the first wiring pattern to transfer a first word line signal output from the first word line driver to the first wiring pattern.

According to some implementations of the present disclosure, there is provided an integrated circuit including a cell region in which a plurality of bit cells are arranged and a peripheral region in which a plurality of word line drivers respectively connected to the plurality of bit cells are arranged, wherein a first bit cell of the plurality of bit cells includes a first transfer transistor connected to a first word line and a second transfer transistor connected to the first word line, the cell region includes a first wiring pattern in a front side wiring layer and including the first word line and a backside wiring pattern in a backside wiring layer and electrically connected to the first wiring pattern, the peripheral region includes a second wiring pattern in the front side wiring layer and connected between an output terminal of a first word line driver of the plurality of word line drivers and the first wiring pattern, the second wiring pattern is directly connected to the first wiring pattern, and each of the first and second transfer transistors receives a first word line signal from the first word line driver through the second wiring pattern and the first wiring pattern.

According to some implementations of the present disclosure, there is provided an integrated circuit including a cell region in which a plurality of bit cells are arranged and a first bit cell of the plurality of bit cells includes a first transfer transistor connected to a first word line and a peripheral region including a first word line driver connected to the first bit cell, wherein the cell region includes a first wiring pattern extending toward the peripheral region in a fist direction in a front side wiring layer and including the first word line and a backside wiring pattern in a backside wiring layer and electrically connected to the first wiring pattern, the peripheral region includes a second wiring pattern extending toward the cell region in the first direction in the front side wiring layer and directly connected between an output terminal of the first word line driver and the first wiring pattern, and the first transfer transistor receives a first word line signal from the first word line driver through the second wiring pattern and the first wiring pattern.

### BRIEF DESCRIPTION OF THE DRAWINGS

FIG. 1 is a block diagram illustrating an example of a memory device;

FIG. 2 is a circuit diagram illustrating an example of a bit cell array;

FIG. 3 is a top view illustrating an example of a memory device;

FIG. 4 is a top view illustrating an example of a memory device;

FIG. 5 is a circuit diagram illustrating an example of a bit cell and a word line driver;

FIG. 6 is a circuit diagram illustrating an example of a word line driver;

FIG. 7 is a circuit diagram illustrating examples of word line drivers included in a row decoder;

FIG. 8 is a circuit diagram illustrating modeling of a word line resistor connected between a bit cell array and a peripheral circuit;

FIG. 9 illustrates a layout of an example of an integrated circuit;

FIG. 10 is a cross-sectional view of an example of the integrated circuit taken along line X1-X1′ of FIG. 9;

FIG. 11 is a cross-sectional view of another example of the integrated circuit taken along line X1-X1′ of FIG. 9;

FIG. 12 illustrates a layout of an example of an integrated circuit;

FIG. 13 is a cross-sectional view of an example of the integrated circuit taken along line X2-X2′ of FIG. 12;

FIG. 14 is a cross-sectional view of another example of the integrated circuit taken along line X2-X2′ of FIG. 12;

FIGS. 15A to 15D are perspective views of examples of devices; and

FIG. 16 is a flowchart illustrating an example of a method of manufacturing an integrated circuit.

### DETAILED DESCRIPTION

Like reference numerals in the drawings denote like elements, and thus their repetitive description will be omitted.

In the specification, the X-axis direction may be referred to as a first direction, the Y-axis direction may be referred to as a second direction, and the Z-axis direction may be referred to as the vertical direction. The plane formed by the X axis and the Y axis may be referred to as a horizontal plane, a component relatively disposed in the +Z-axis direction compared to another component may be described as the component being on the other component, and a component relatively disposed in the −Z-axis direction compared to another component may be described as the component being beneath the other component.

An integrated circuit (IC) may be designed by arranging a plurality of standard cells. A standard cell is a unit of the layout of an IC and may be referred to as a cell. A standard cell may be designed to include a plurality of transistors for performing a predefined function. A standard cell is designed and verified in advance and then registered in a standard cell library, and an IC may be designed by using a computer aided design to perform logic design, placement, and routing through a combination of standard cells.

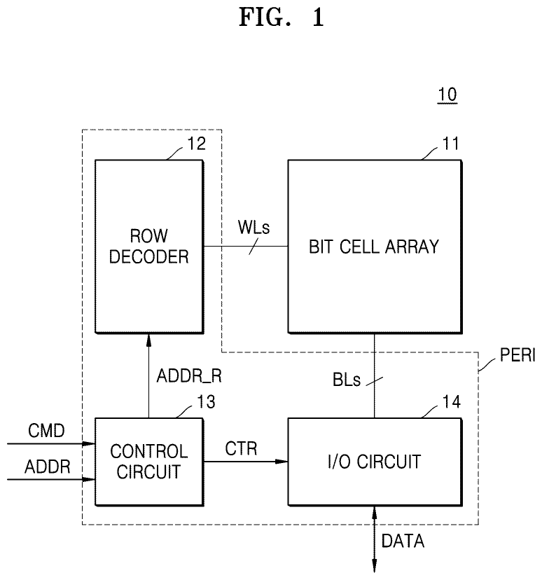

FIG. 1 is a block diagram illustrating an example of a memory device 10.

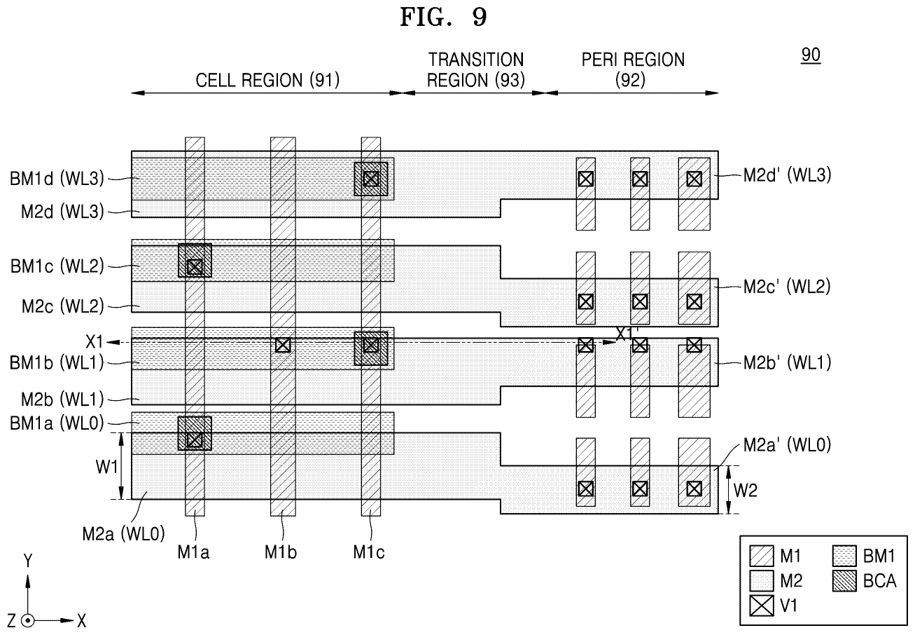

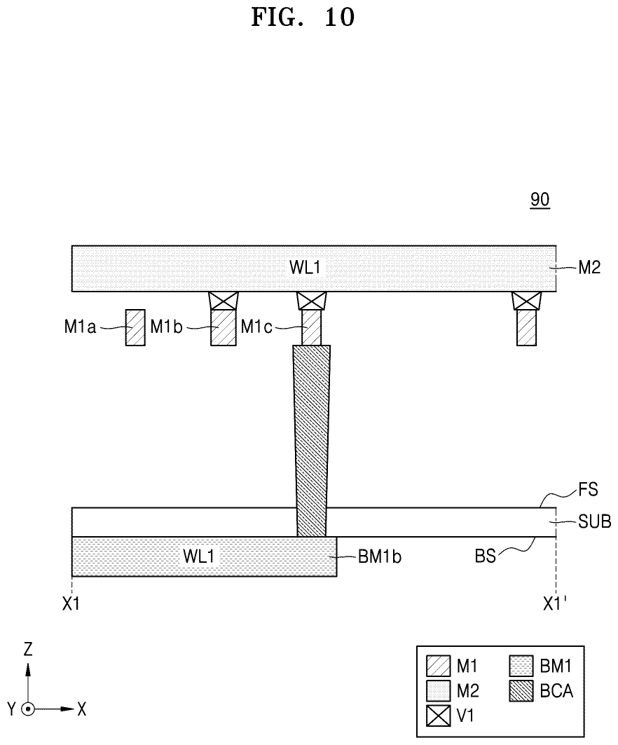

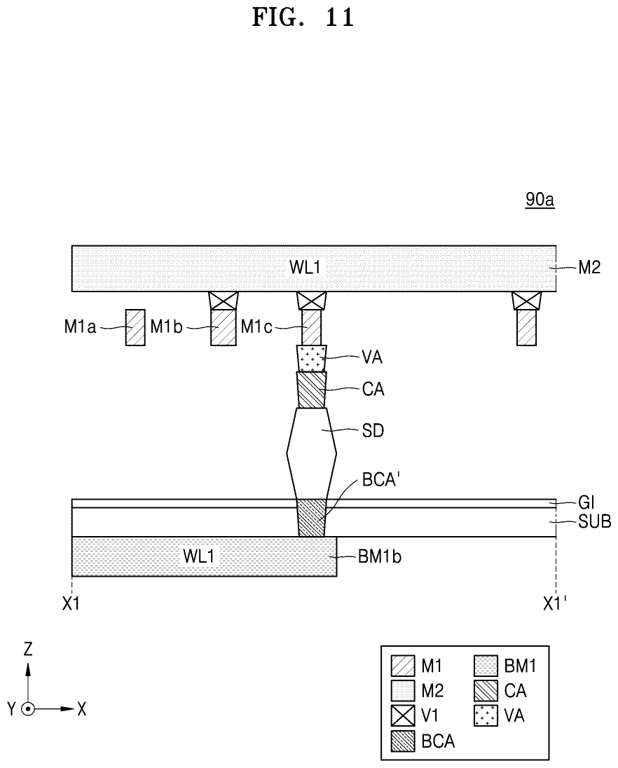

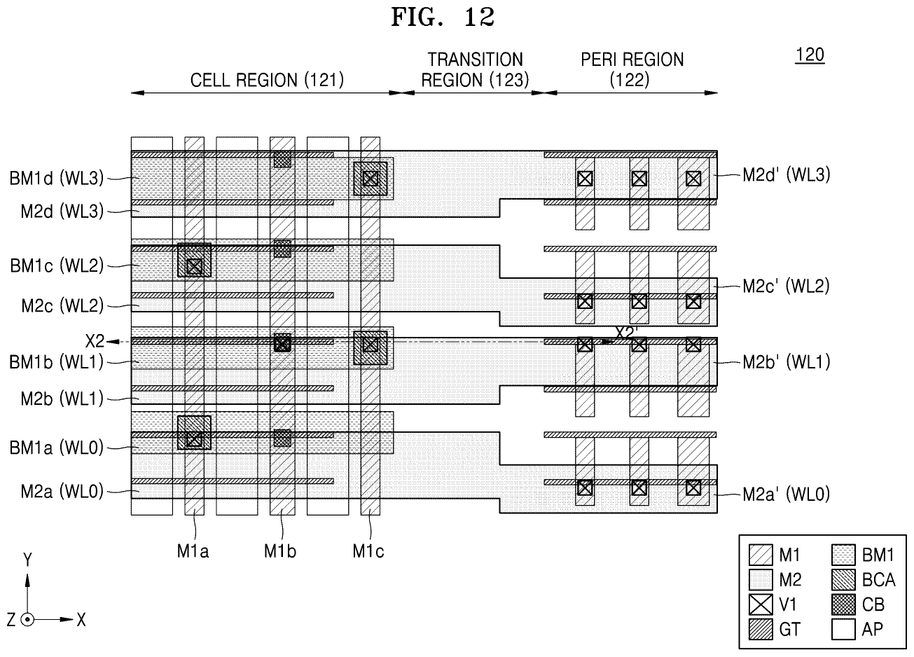

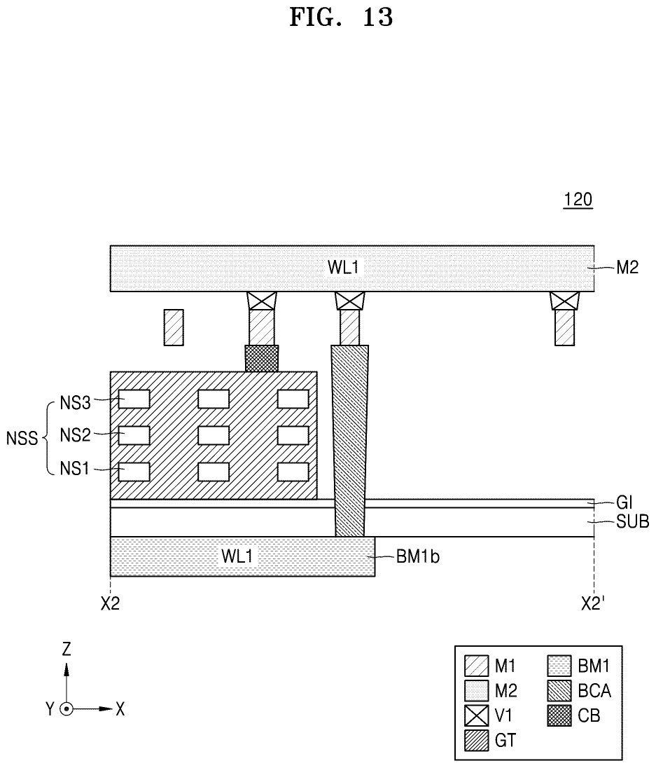

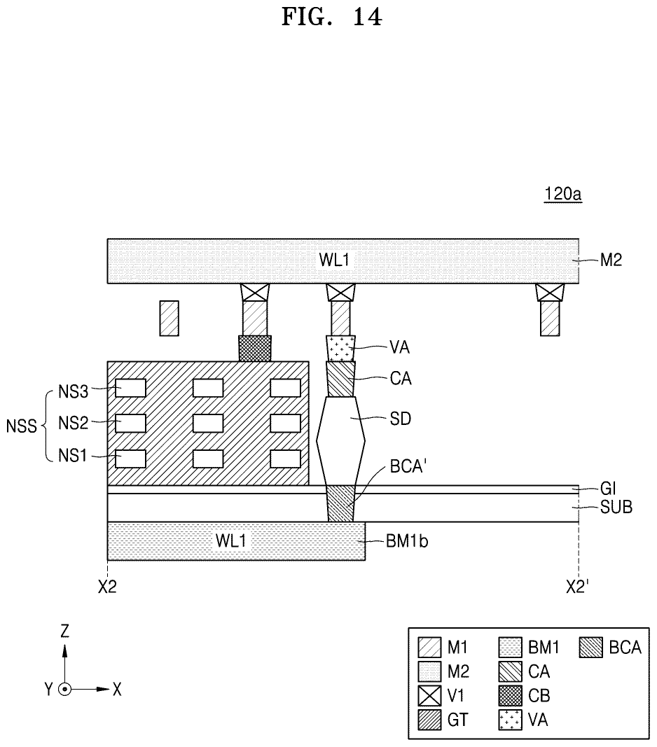

Referring to FIG. 1, the memory device 10 may include a bit cell array 11, a row decoder 12, a control circuit 13, and an input/output (I/O) circuit 14. Herein, the row decoder 12, the control circuit 13, and the I/O circuit 14 may be collectively referred to as a peripheral circuit PERI. In some implementations, the peripheral circuit PERI may further include a command buffer, an address buffer, a voltage generator, and/or the like. For example, a partial area of the memory device 10 may be implemented by an IC 90 of FIGS. 9 and 10, an IC 90a of FIG. 11, an IC 120 of FIGS. 12 and 13, or an IC 120a of FIG. 14.

The memory device 10 may receive a command CMD, an address ADDR, and data DATA. For example, the memory device 10 may receive the command CMD indicating write, the address ADDR, and the data DATA and store the received data DATA in a region of the bit cell array 11 corresponding to the address ADDR. In addition, the memory device 10 may receive the command CMD indicating read and the address ADDR and output, to the outside, the data DATA stored in the region of the bit cell array 11 corresponding to the address ADDR.

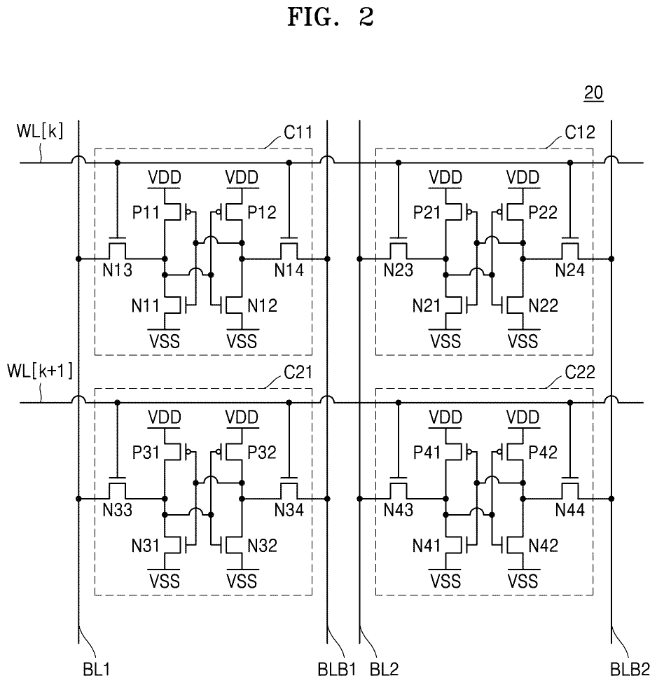

The bit cell array 11 may include a plurality of bit cells or memory cells accessed by a plurality of word lines WLs and a plurality of bit lines BLs. In some implementations, the plurality of bit cells included in the bit cell array 11 may be volatile memory cells, such as static random access memory (SRAM) and dynamic random access memory (DRAM). In some implementations, the plurality of memory cells included in the bit cell array 11 may be non-volatile memory cells, such as resistive random access memory (RRAM). Examples herein are described by mainly referring to SRAM, as described below with reference to FIG. 2, but the scope of this disclosure is not limited thereto.

The control circuit 13 may generate a row address ADDR_R and a control signal CTR based on the command CMD and the address ADDR. For example, the control circuit 13 may identify a read command by decoding the command CMD and generate the row address ADDR_R and the control signal CTR to read the data DATA from the bit cell array 11. In addition, the control circuit 13 may identify a write command by decoding the command CMD and generate the row address ADDR_R and the control signal CTR to write the data DATA on the bit cell array 11.

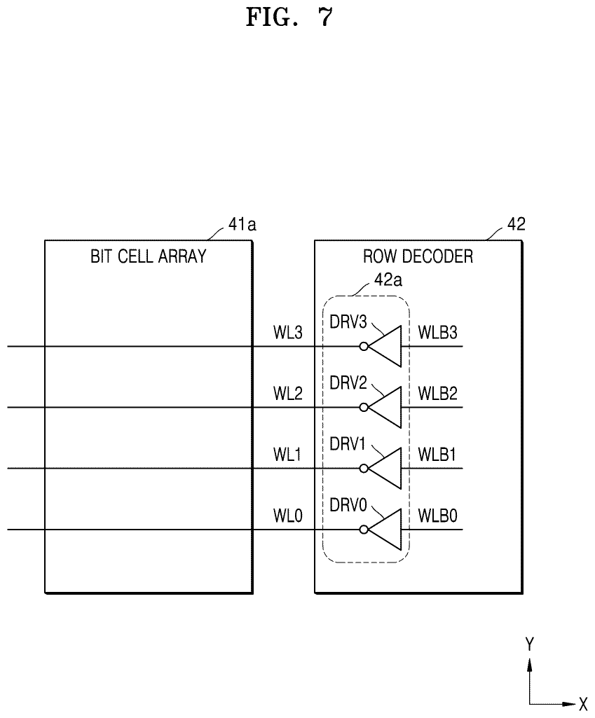

The row decoder 12 may be connected to the bit cell array 11 through the plurality of word lines WLs and enable one of the plurality of word lines WLs in response to the row address ADDR_R. Accordingly, bit cells connected to the enabled word line may be selected from among the plurality of bit cells included in the bit cell array 11. For example, the row decoder 12 may include a row driver (e.g., 42a of FIG. 7).

The I/O circuit 14 may be connected to the bit cell array 11 through the plurality of bit lines BLs and perform a read operation or a write operation in response to the control signal CTR. For example, the I/O circuit 14 may include a column driver. The column driver may sense the currents and/or voltages of the plurality of bit lines BLs or apply currents and/or voltages to the plurality of bit lines BLs, at a timing determined based on the control signal CTR.

In some implementations, the I/O circuit 14 may include a plurality of logic cells or a plurality of standard cells. In some implementations, the plurality of standard cells may be referred to as a plurality of I/O slices. For example, the plurality of standard cells may be respectively connected to the plurality of bit cells through the plurality of bit lines BLs. For example, the plurality of standard cells may include write/read circuits. For example, the plurality of standard cells may include sense amplifiers. For example, the plurality of standard cells may include column drivers or write drivers.

Along with the progress of process refinement, the width of a metal track may decrease, and accordingly, the number of allowable tracks may also be limited. Accordingly, the resistance between a metal and a contact/via may increase, and a routing resource may be insufficient. According to some implementations of the present disclosure, a backside power distribution network (BSPDN) for supplying a signal and/or power by using a backside wiring layer may be used to increase the width of a wiring, e.g., the width of a metal track, included in a front side wiring layer. In addition, because the degree of routing freedom of the front side wiring layer is improved using a BSPDN process, when a signal is transferred between the bit cell array 11 and the peripheral circuit PERI, the signal may be transferred through direct connection between wiring patterns in the same layer instead of a detour path through several metal layers and several via layers. For example, because a transfer path for a word line signal is reduced through such direct connection, the length of a word line wiring may be significantly reduced, and accordingly, a wiring resistance may be reduced, thereby improving the performance of the memory device 10.

As described above, in some implementations, in the IC including the memory device 10, a wiring resistance may be reduced through direct connection of wirings in the same layer between the bit cell array 11 and the peripheral circuit PERI, thereby improving the operating speed of the IC. In this case, a signal supplied from a peripheral circuit may be supplied to the bit cell array 11 not through a detour path but through a direct connection path, thereby improving the power performance area (PPA) of the IC.

In addition, or alternatively, in the IC including the memory device 10, a word line signal and/or power may be supplied to the bit cell array 11 by using a backside wiring layer, thereby improving the degree of routing freedom of a front side wiring layer and increasing the wiring width of the front side wiring layer. In some implementations, the IC may have a direct backside contact (DBC) structure including backside contacts disposed on the backside wiring layer, thereby further decreasing a resistance to the backside wiring layer.

FIG. 2 is a circuit diagram illustrating an example of a bit cell array 20. Referring to FIG. 2, the bit cell array 20 may include bit cells C11, C12, C21, and C22 adjacent to each other. For example, the bit cell array 20 may correspond to one example of the bit cell array 11 of FIG. 1. The bit cell C11 and the bit cell C12 arranged in the same row may be commonly connected to a word line WL[k], and the bit cell C21 and the bit cell C22 arranged in the same row may be commonly connected to a word line WL[k+1] (k is an integer greater than or equal to 0). In addition, the bit cell C11 and the bit cell C21 arranged in the same column may be connected to a first bit line BL1 and a first complementary bit line BLB1, and the bit cell C12 and the bit cell C22 arranged in the same column may be connected to a second bit line BL2 and a second complementary bit line BLB2.

The bit cell C11 may include P-type transistors P11 and P12 and N-type transistors N11 to N14 and may be a six-transistor (6T) SRAM cell. The bit cell C11 may include an inverter pair cross-coupled between a node to which a positive supply voltage (or a cell voltage) VDD is applied and a node to which a negative supply voltage (or a ground voltage) VSS is applied. For example, a first inverter of the cross-coupled inverter pair may include the P-type transistor P11 and the N-type transistor N11, and a second inverter of the cross-coupled inverter pair may include the P-type transistor P12 and the N-type transistor N12.

In addition, the N-type transistors N13 and N14 may be referred to as transfer transistors or pass transistors configured to connect the first inverter and the second inverter to the first bit line BL1 and the first complementary bit line BLB1, respectively, by the word line WL[k] that is enabled (e.g., has a high-level voltage). Hereinafter, the N-type transistor N13 is referred to as a first transfer transistor N13, and the N-type transistors N14 is referred to as a second transfer transistor N14.

As shown in FIG. 2, the bit cells C12, C21, and C22 may have the same structure as the bit cell C11, and accordingly, the description of the bit cell C11 may be applied to the bit cells C12, C21, and C22. The bit cell C12 may include P-type transistors P21 and P22 and N-type transistors N21 to N24. The N-type transistors N23 and N24 may be configured to connect a first inverter including the P-type transistor P21 and the N-type transistor N21 and a second inverter including the P-type transistor P22 and the N-type transistor N22 to the second bit line BL2 and the second complementary bit line BLB2, respectively, by the word line WL[k] that is enabled.

The bit cell C21 may include P-type transistors P31 and P32 and N-type transistors N31 to N34. The N-type transistors N33 and N34 may be configured to connect a first inverter including the P-type transistor P31 and the N-type transistor N31 and a second inverter including the P-type transistor P32 and the N-type transistor N32 to the first bit line BL1 and the first complementary bit line BLB1, respectively, by the word line WL[k+1] that is enabled. The bit cell C22 may include P-type transistors P41 and P42 and N-type transistors N41 to N44. The N-type transistors N43 and N44 may be configured to connect a first inverter including the P-type transistor P41 and the N-type transistor N41 and a second inverter including the P-type transistor P42 and the N-type transistor N42 to the second bit line BL2 and the second complementary bit line BLB2, respectively, by the word line WL[k+1] that is enabled.

In some implementations, each of the bit cells C11 to C22 may include at least one gate-all-around (GAA) transistor. For example, each of the P-type transistors P11 to P42 and the N-type transistors N11 to N44 may be implemented by a GAA transistor. A GAA transistor may include a gate line extending in the first direction (e.g., X of FIG. 9) and an active pattern extending in the second direction (e.g., Y of FIG. 9), wherein the gate line surrounds the active pattern and a gate insulating layer is between the gate line and the active pattern. A GAA transistor is described below with reference to FIGS. 13 and 14.

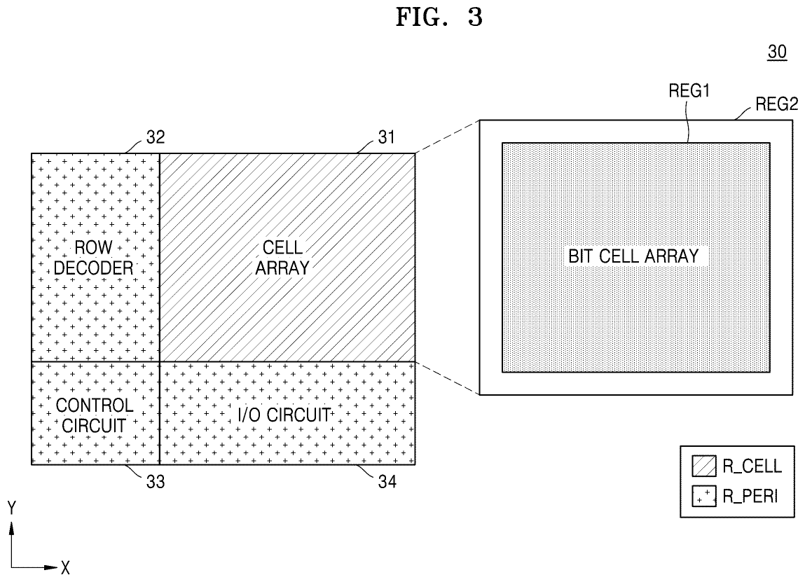

FIG. 3 is a top view illustrating an example of a memory device 30. Referring to FIG. 3, the memory device 30 may include at least one cell array arranged in a cell region R_CELL and a peripheral circuit arranged in a peripheral region R_PERI. For example, the memory device 30 may be one example of the layout of an IC corresponding to the memory device 10 of FIG. 1. For example, a cell array 31 may be arranged in the cell region R_CELL, and a row decoder 32, a control circuit 33, and an I/O circuit 34 may be arranged in the peripheral region R_PERI. In some implementations, the row decoder 32 may be referred to as a row driver, and the I/O circuit 34 may be referred to as a column driver.

The cell region R_CELL may include a cell array region REG1 and a transition region REG2. A plurality of bit cells may be arranged in the cell array region REG1. The transition region REG2 surrounds the cell array region REG1 and may be referred to as a dummy region, an outer region, or a termination region. The row decoder 32 may be arranged adjacent to the cell array 31 in a first direction X. The I/O circuit 34 may be arranged adjacent to the cell array 31 in a second direction Y.

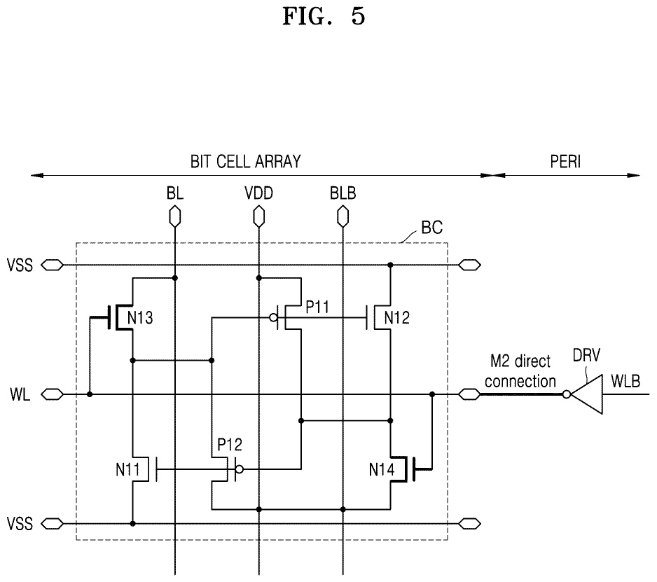

In some implementations, signal wirings connected to the row decoder 32 may be implemented by a front side wiring layer (e.g., M1 and M2 of FIG. 9) disposed on the front side of a substrate, and power wirings connected to the row decoder 32 may be implemented by a backside wiring layer (e.g., BM1 of FIG. 9) disposed on the backside of the substrate. For example, the backside wiring layer connected to the row decoder 32 may overlap the row decoder 32 in the vertical direction. Hereinafter, a partial area of the cell array 31 and the row decoder 32 are described in detail with reference to FIGS. 5 to 14.

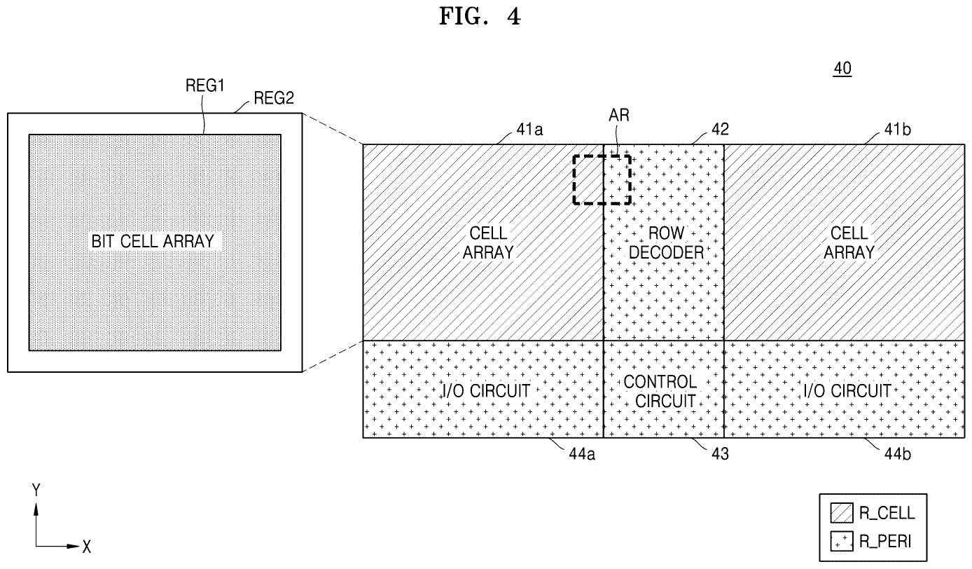

FIG. 4 is a top view illustrating an example of a memory device 40.

Referring to FIG. 4, the memory device 40 may include at least one cell array arranged in the cell region R_CELL and a peripheral circuit arranged in the peripheral region R_PERI. For example, the memory device 40 may be one example of the layout of an IC corresponding to the memory device 10 of FIG. 1. For example, first and second cell arrays 41a and 41b may be arranged in the cell region R_CELL, and a row decoder 42, a control circuit 43, and first and second I/O circuits 44a and 44b may be arranged in the peripheral region R_PERI.

For example, the first cell array 41a may include the cell array region REG1 and the transition region REG2. A plurality of bit cells may be arranged in the cell array region REG1. The transition region REG2 surrounds the cell array region REG1 and may be referred to as a dummy region, an outer region, or a termination region. The row decoder 42 may be arranged adjacent to the first cell array 41a in the first direction X and arranged between the first and second cell arrays 41a and 41b. The first I/O circuit 44a may be arranged adjacent to the first cell array 41a in the second direction Y. Hereinafter, a partial area AR of the first cell array 41a and the row decoder 42 is described in detail with reference to FIGS. 5 to 14. In some embodiments herein, for the sake of simplicity, the terms “cell array” and “bit cell array” may be used interchangeably.

FIG. 5 is a circuit diagram illustrating an example of a bit cell BC and a word line driver DRV.

Referring to FIG. 5, the bit cell BC may be included in a bit cell array (e.g., 11 of FIGS. 1, 31 of FIG. 3, or 41a or 41b of FIG. 4) and, for example, correspond to one of the bit cells C11 to C22 of FIG. 2. The description made above with reference to FIG. 2 may also be applied to the circuit of FIG. 5. The word line driver DRV may be included in the peripheral circuit PERI, for example, a row decoder (e.g., 12 of FIGS. 1, 32 of FIG. 3, or 42 of FIG. 4).

According to some implementations of the present disclosure, the bit cell BC and the word line driver DRV may be directly connected to each other through a front side wiring layer, e.g., a second front side wiring layer (e.g., M2 of FIG. 9). For example, the bit cell BC may directly receive a word line signal WL from the word line driver DRV through the second front side wiring layer M2. In some conventional memory devices, the word line signal WL output from the word line driver DRV is provided to the bit cell BC through a plurality of wiring layers and a plurality of vias (e.g., from M2-M3 (e.g., a third front side wiring layer above M2)-M4 (e.g., a fourth front side wiring layer above M3) of the word line driver DRV to M3-M2-M1 (e.g., a first front side wiring layer below M2) of the bit cell array), and thus, a wiring through which the word line signal WL is transferred is considerably long, and accordingly, a wiring resistance is considerably large. However, according to some implementations of the present disclosure, the word line signal WL output from the word line driver DRV is directly provided to the bit cell BC through the front side wiring layer, e.g., the second front side wiring layer M2, and thus, a wiring through which the word line signal WL is transferred is short, and accordingly, a wiring resistance is considerably reduced.

For example, the word line signal WL output from the word line driver DRV may be applied to a first gate of the first transfer transistor N13 through the second front side wiring layer M2. Herein, the first transfer transistor N13 may include the first gate which receives the word line signal WL and a first source/drain connected to a bit line BL. In addition, the word line signal WL output from the word line driver DRV may be applied to a second gate of the second transfer transistor N14 through the second front side wiring layer M2. Herein, the second transfer transistor N14 may include the second gate which receives the word line signal WL and a second source/drain connected to a complementary bit line BLB.

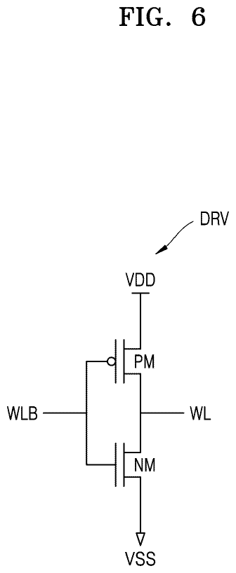

FIG. 6 is a circuit diagram illustrating an example of the word line driver DRV.

Referring to FIG. 6, the word line driver DRV may include a P-type transistor, e.g., a P-type metal-oxide-semiconductor (PMOS) transistor PM, and an N-type transistor, e.g., an N-type metal-oxide-semiconductor (NMOS) transistor NM, and the PMOS transistor PM may be connected in series to the NMOS transistor NM. The PMOS transistor PM may include a source which receives a power supply voltage VDD, a gate which receives an input signal, e.g., a complementary word line signal WLB, and a drain which outputs the word line signal WL. The NMOS transistor NM may include a source which receives a ground voltage VSS, a gate which receives an input signal, e.g., the complementary word line signal WLB, and a drain which outputs the word line signal WL.

Referring to FIGS. 5 and 6, the drain of the PMOS transistor PM and the drain of the NMOS transistor NM may output the word line signal WL through the second front side wiring layer M2. The word line signal WL may be provided to each of the first gate of the first transfer transistor N13 and the second gate of the second transfer transistor N14 through the second front side wiring layer M2. Accordingly, in some implementations, the length of a wiring through which the word line signal WL is transferred to the first gate of the first transfer transistor N13 may be reduced, thereby reducing a wiring resistance. In addition, in some implementations, the length of a wiring through which the word line signal WL is transferred to the second gate of the second transfer transistor N14 may be reduced, thereby reducing a wiring resistance.

FIG. 7 is a circuit diagram illustrating examples of word line drivers 42a included in the row decoder 42.

Referring to FIG. 7, the row decoder 42 may include the word line drivers 42a, and the word line drivers 42a may be connected to the first cell array 41a through a plurality of word lines. For example, the word line drivers 42a may include first to fourth word line drivers DRV0 to DRV3. The first word line driver DRV0 may receive a first complementary word line signal WLB0 and provide a first word line signal WL0. The second word line driver DRV1 may receive a second complementary word line signal WLB1 and provide a second word line signal WL1. The third word line driver DRV2 may receive a third complementary word line signal WLB2 and provide a third word line signal WL2. The fourth word line driver DRV3 may receive a fourth complementary word line signal WLB3 and provide a fourth word line signal WL3.

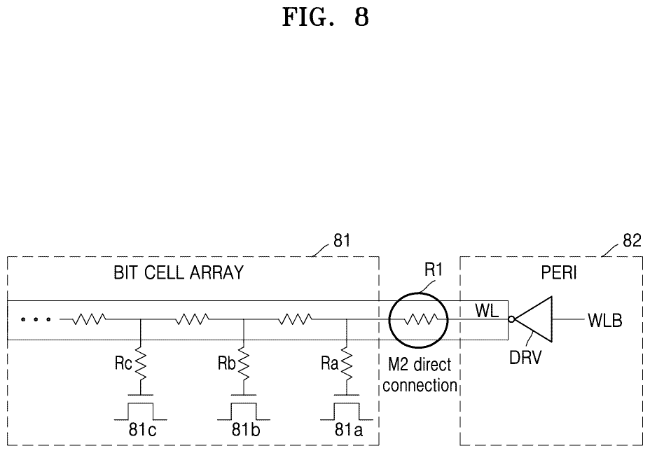

FIG. 8 is a circuit diagram illustrating modeling of a word line resistor connected between a bit cell array 81 and a peripheral circuit 82.

Referring to FIG. 8, the peripheral circuit 82 may include the word line driver DRV, and the word line driver DRV may output the word line signal WL based on the complementary word line signal WLB. According to some implementations of the present disclosure, the word line signal WL may be transferred to the bit cell array 81 by direct connection through the second front side wiring layer M2. Through such direct connection, the resistance of a word line resistor R1 between the word line driver DRV and the bit cell array 81 may be considerably reduced. Herein, the word line resistor R1 may correspond to the resistance of the second front side wiring layer M2.

The bit cell array 81 may include a plurality of transfer transistors 81a, 81b, and 81c. For example, the plurality of transfer transistors 81a, 81b, and 81c may be included in a plurality of bit cells of the bit cell array 81, respectively. For example, the transfer transistor 81a may be included in a first bit cell, and the resistance of a resistor Ra between the word line resistor R1 and the transfer transistor 81a may include the resistances of a first front side wiring layer M1 (see FIG. 9) and a via V1 (see FIG. 9). For example, the transfer transistor 81b may be included in a second bit cell, and the resistance of a resistor Rb between the word line resistor R1 and the transfer transistor 81b may include the resistances of the first front side wiring layer M1 and the via V1. For example, the transfer transistor 81c may be included in a third bit cell, and the resistance of a resistor Rc between the word line resistor R1 and the transfer transistor 81c may include the resistances of the first front side wiring layer M1 and the via V1.

FIG. 9 illustrates a layout of an example of an IC 90. FIG. 10 is a cross-sectional view of an example of the IC 90 taken along line X1-X1′ of FIG. 9.

Referring to FIGS. 9 and 10, the IC 90 may include a cell region 91 and a peripheral region 92, and the cell region 91 may be spaced apart from the peripheral region 92 in the first direction X. A region between the cell region 91 and the peripheral region 92 may be referred to as a transition region 93. For example, the IC 90 may correspond to a partial area of the memory device 10 of FIG. 1. For example, the cell region 91 may include the bit cell array 11 of FIG. 1, and the peripheral region 92 may include the row decoder 12 of FIG. 1.

In some implementations, the IC 90 may correspond to the partial area AR of FIG. 4. For example, the cell region 91 may correspond to the cell array region REG1 of FIG. 4. For example, the plurality of bit cells included in the first cell array 41a may be arranged in the cell region 91. For example, the transition region 93 may correspond to the transition region REG2 of FIG. 4. For example, a plurality of word line drivers included in the row decoder 42 may be arranged in the peripheral region 92.

The IC 90 may include a front side wiring layer (e.g., M1 and M2) disposed on a front side FS of a substrate SUB and a backside wiring layer (e.g., BM1) disposed on a backside BS of the substrate SUB, and a power distribution network (PDN) may be implemented using the front side wiring layer and the backside wiring layer. Accordingly, some of signals and/or power applied to the IC 90 may be transferred through the front side wiring layer, in other words, a front side PDN (FSPDN), and the rest may be transferred through the backside wiring layer, in other words, a backside PDN (BSPDN). Therefore, according to some implementations of the present disclosure, compared to a structure in which wirings are disposed on only the front side FS of the substrate SUB, routing complexity may be significantly reduced, and the length of each wiring or each via may also be reduced, thereby improving the performance of the IC 90.

For example, the IC 90 may include the first front side wiring layer M1, the second front side wiring layer M2, vias V1, a first backside wiring layer BM1, and backside contacts BCA. The substrate SUB may include a semiconductor material, such as silicon, germanium, or silicon-germanium, or a group III-V compound, such as gallium arsenide (GaAs), aluminum gallium arsenide (AlGaAs), indium arsenide (InAs), indium gallium arsenide (InGaAs), indium antimonide (InSb), gallium antimonide (GaSb), indium gallium antimonide (InGaSb), indium phosphide (InP), gallium phosphide (GaP), indium gallium phosphide (InGaP), indium nitride (InN), gallium nitride (GaN), or indium gallium nitride (InGaN). For example, the substrate SUB may be a silicon-on-insulator (SOI) substrate or a germanium-on-insulator (GOI) substrate. For example, the substrate SUB may be a P-type substrate doped with P-type impurities.

Active areas may be disposed on the substrate SUB. The active areas may be limited by a device isolation layer (e.g., shallow trench isolation (STI)). For example, a first active area may include an N well doped with N-type impurities, wherein a P-type transistor, e.g., a P-type gate-all-around field-effect transistor (GAAFET), may be formed in the N well. For example, a second active area may include a P well doped with P-type impurities, wherein an N-type transistor, e.g., an N-type GAAFET, may be formed in the P well.

The first front side wiring layer M1 may include a plurality of wiring patterns each extending in the second direction Y on the front side FS of the substrate SUB and spaced apart from each other in the first direction X. The vias V1 may be disposed on the plurality of wiring patterns of the first front side wiring layer M1. For example, the first front side wiring layer M1 may include wiring patterns M1a, M1b, and M1c disposed in the cell region 91.

The second front side wiring layer M2 may include a plurality of wiring patterns each extending in the first direction X on the first front side wiring layer M1 and spaced apart from each other in the second direction Y. The second front side wiring layer M2 may include first wiring patterns M2a to M2d disposed in the cell region 91 and second wiring patterns M2a′ to M2d′ disposed in the peripheral region 92. In the transition region 93, the first wiring patterns M2a to M2d may be connected to the second wiring patterns M2a′ to M2d′, respectively. Accordingly, the plurality of wiring patterns included in the second front side wiring layer M2 may be implemented in the form of a jog pattern or a jogging pattern.

In some implementations, each of the first wiring patterns M2a to M2d may have a first width W1 in the second direction Y, and each of the second wiring patterns M2a′ to M2d′ may have a second width W2 that is less than the first width W1 in the second direction Y. However, the widths are not limited thereto, and in some implementations, the first wiring patterns M2a to M2d may have different widths, and/or the second wiring patterns M2a′ to M2d′ may also have different widths. In some implementations, the IC 90 may include the first backside wiring layer BM1 such that the first width W1 of each of the first wiring patterns M2a to M2d included in the second front side wiring layer M2 increases. Accordingly, the first wiring patterns M2a to M2d each having the first width W1 that is relatively large may be directly connected to the second wiring patterns M2a′ to M2d′ each having the second width W2 that is relatively small, respectively.

The first backside wiring layer BM1 may be disposed on the backside BS of the substrate SUB. For example, the first backside wiring layer BM1 may include backside wiring patterns BM1a to BM1d each extending in the first direction X and spaced apart from each other in the second direction Y. However, the wiring configuration is not limited thereto, and the arrangement and/or the extension direction of the backside wiring patterns BM1a to BM1d may vary in various implementations.

The backside contacts BCA may be disposed on the backside wiring patterns BM1a to BM1d, respectively. The backside contacts BCA may pass through the substrate SUB in a vertical direction Z. In some implementations, the backside contacts BCA may extend on the substrate SUB in the vertical direction Z, and accordingly, may electrically connect the backside wiring patterns BM1a to BM1d to the first front side wiring layer M1, respectively. In some implementations, the IC 90 may further include backside vias disposed between the backside wiring patterns BM1a to BM1d and the backside contacts BCA. In some implementations, the IC 90 may further include through-vias disposed on the backside contacts BCA, and the backside contacts BCA may be electrically connected to the first front side wiring layer M1 through the through-vias. As described above, a plurality of conductive layers, such as a via and a contact, may be disposed between the backside wiring patterns BM1a to BM1d and the first front side wiring layer M1.

In some implementations, the backside wiring patterns BM1a to BM1d may be electrically connected to the first front side wiring layer M1 through the backside contacts BCA and electrically connected to the second front side wiring layer M2 through the vias V1 on the first front side wiring layer M1. Accordingly, the first to fourth word line signals WL0 to WL3 respectively output from the plurality of word line drivers included in the peripheral region 92 may be respectively transferred to the backside wiring patterns BM1a to BM1d through the second wiring patterns M2a′ to M2d′, the first wiring patterns M2a to M2d, the vias V1, the wiring patterns M1a and M1c, and the backside contacts BCA.

For example, the backside wiring pattern BM1b may be electrically connected to the wiring pattern M1c through a backside contact BCA, and the wiring pattern M1c may be electrically connected to the second front side wiring layer M2 through a via V1. Accordingly, the word line signal WL1 output from a word line driver of the peripheral region 92 may be transferred to the backside wiring pattern MB1b through the second wiring pattern M2b′, the first wiring pattern M2b, the via V1, the wiring pattern M1c, and a backside contact BCA.

FIG. 11 is a cross-sectional view of another example of the integrated circuit 90 taken along line X1-X1′ of FIG. 9.

Referring to FIG. 11, the IC 90a corresponds to a modified example of the IC 90 of FIGS. 9 and 10, and the description made above with reference to FIGS. 9 and 10 may also be applied to the circuit configuration of FIG. 11. A gate insulating layer GI may be disposed on the substrate SUB. A source/drain SD, a source/drain contact CA, and a via VA may be disposed between the substrate SUB and the first front side wiring layer M1. According to the present example, the height of a backside contact BCA′ in the vertical direction Z may be less than the height of the backside contact BCA of FIG. 10 in the vertical direction Z. For example, the height of the backside contact BCA′ may be similar to the height of the substrate SUB.

FIG. 12 illustrates a layout of an example of an IC 120. FIG. 13 is a cross-sectional view of an example of the integrated circuit IC 120 taken along line X2-X2′ of FIG. 12.

Referring to FIGS. 12 and 13, the integrated circuit IC 120 may include a cell region 121 and a peripheral region 122, and the cell region 121 may be spaced apart from the peripheral region 122 in the first direction X. A region between the cell region 121 and the peripheral region 122 may be referred to as a transition region 123. For example, the IC 120 may correspond to a partial area of the memory device 10 of FIG. 1. For example, the cell region 121 may include the bit cell array 11 of FIG. 1, and the peripheral region 122 may include the row decoder 12 of FIG. 1.

The IC 120 corresponds to an example of the IC 90 of FIG. 9 and may further include gate lines GT, gate contacts CB, and active patterns AP in addition to the IC 90 of FIG. 9. The description made above with reference to FIGS. 9 to 11 may also be applied to the IC 120. Hereinafter, the differences between the IC 120 and the IC 90 of FIG. 9 are mainly described.

The gate lines GT may each extend in the first direction X and may be spaced apart from each other in the second direction Y. The gate contacts CB may be disposed on some of the gate lines GT, respectively. Some of the gate lines GT may be electrically connected to the first front side wiring layer M1 through the gate contacts CB. The gate lines GT may be defined as conductive segments including a conductive material, such as polysilicon or one or more metals.

The gate insulating layer GI may be disposed on the substrate SUB. The active patterns AP, e.g., nanosheets, may be formed on the gate insulating layer GI. In this case, the nanosheets may function as a channel of a transistor. The active patterns AP may each extend in the second direction Y on the substrate SUB and may be separated from each other in the first direction X. For example, each active pattern AP may include a nanosheet stack NSS, and the nanosheet stack NSS may include nanosheets NS1 to NS3 spaced apart from each other in the vertical direction Z. For example, a multi-bridge channel field-effect transistor (MBCFET), in which the nanosheets NS1 to NS3 are stacked and a gate line GT surrounds the nanosheets NS1 to NS3, may be formed on an active area. However, the IC 120 is not limited to including MBCFET transistors. For example, the IC 120 may include a GAAFET, in which a nanowire is surrounded by a gate line, formed on an active area, or another transistor type.

Hereinafter, the IC 120 is described in detail with reference to FIGS. 5, 7, 12, and 13.

In some implementations, a plurality of bit cells may be arranged in the cell region 121, and the first to fourth word line drivers DRV0 to DRV3 may be arranged in the peripheral region 122. The cell region 121 may include a first gate line extending in the first direction X above the substrate SUB, a first wiring pattern (one of M2a to M2d) disposed on a front side wiring layer (e.g., the second front side wiring layer M2) above the first gate line and electrically connected to the first gate line, a backside contact BCA passing through the substrate SUB in the vertical direction Z, and a backside wiring pattern (one of BM1a to BM1d) disposed on the backside of the substrate SUB and electrically connected to the first wiring pattern (one of M2a to M2d) through the backside contact BCA.

The peripheral region 122 may include a second wiring pattern (one of M2a′ to M2d′) disposed on the front side wiring layer (e.g., the second front side wiring layer M2) and directly connected to the first wiring pattern (one of M2a to M2d) to transfer a word line signal (one of WL0 to WL3) output from a word line driver (one of DRV0 to DRV3) to the first wiring pattern (one of M2a to M2d). For example, the first front side wiring layer M1, the second front side wiring layer M2, the gate lines GT, and the vias V1 arranged in the peripheral region 122 may constitute the first to fourth word line drivers DRV0 to DRV3.

In some implementations, the first wiring pattern (one of M2a to M2d) may extend toward the peripheral region 122 in the first direction X. In some implementations, the second wiring pattern (one of M2a′ to M2d′) may extend toward the cell region 121 in the first direction X and may be directly connected to the first wiring pattern (one of M2a to M2d) in the transition region 123 between the cell region 121 and the peripheral region 122.

In some implementations, the cell region 121 may further include a first source/drain connected to the bit line BL, and the first gate and the first source/drain may constitute the first transfer transistor N13 of the bit cell BC among the plurality of bit cells. In some implementations, the cell region 121 may further include a second gate line electrically connected to the first wiring pattern (one of M2a to M2d) and a second source/drain connected to the complementary bit line BLB, and the second gate line and the second source/drain may constitute the second transfer transistor N14 of the bit cell BC.

In some implementations, the cell region 121 may include the first front side wiring layer M1 including a wiring pattern (one of M1a to M1c) extending in the second direction Y above the upper surface of the substrate SUB and the second front side wiring layer M2 disposed above the first front side wiring layer M1 and including the first wiring pattern (one of M2a to M2d). For example, the first gate line may receive one of the first to fourth word line signals WL0 to WL3 from the second wiring pattern (one of M2a′ to M2d′) through the wiring pattern M1b and the first wiring pattern (one of M2a to M2d).

In some implementations, the cell region 121 may further include a gate contact CB between the first gate line and the first front side wiring layer M1 and a via V1 between the wiring pattern (e.g., M1b) and the first wiring pattern (e.g., M2b), and the first gate line may receive the second word line signal WL1 from the second wiring pattern (e.g., M2b′) through the gate contact CB, the wiring pattern M1b, the via V1, and the first wiring pattern M2b.

In some implementations, the first front side wiring layer M1 may further include a wiring pattern (e.g., M1c) extending in the second direction Y, the IC 120 may further include a via V1 between the wiring pattern M1c and the first wiring pattern M2b, and a backside wiring pattern (e.g., BM1b) may receive the second word line signal WL1 from the second wiring pattern (e.g., M2b′) through the backside contact BCA, the wiring pattern M1c, the via V1, and the first wiring pattern M2b.

In some implementations, the first wiring pattern (one of M2a to M2d) may have the first width W1 in the second direction Y, and the second wiring pattern (one of M2a′ to M2d′) may have the second width W2 that is different from the first width W1 in the second direction Y. For example, the first width W1 may be greater than the second width W2. In some implementations, the cell region 121 may further include the nanosheets NS1 to NS3 stacked on the substrate SUB in the vertical direction Z, and each of the plurality of bit cells may include a GAA transistor.

In some implementations, the plurality of bit cells may be arranged in the cell region 121, and the first to fourth word line drivers DRV0 to DRV3 respectively connected to the plurality of bit cells may be arranged in the peripheral region 122. The bit cell BC among the plurality of bit cells may include the first transfer transistor N13 connected to a first word line and the second transfer transistor N14 connected to the first word line. The cell region 121 may include a first wiring pattern (one of M2a to M2d) disposed on a front side wiring layer (e.g., M2) and corresponding to the first word line and a backside wiring pattern (one of BM1a to BM1d) disposed on the backside wiring layer BM1 and electrically connected to the first wiring pattern (one of M2a to M2d).

The peripheral region 122 may include a second wiring pattern (one of M2a′ to M2d′) disposed on the front side wiring layer (e.g., M2) and connected between the output terminal of one of a plurality of word line drivers and the first wiring pattern (one of M2a to M2d), the second wiring pattern (one of M2a′ to M2d′) may be directly connected to the first wiring pattern (one of M2a to M2d), and each of the first and second transfer transistors N13 and N14 may receive a word line signal (one of WL0 to WL3) from the word line driver through the second wiring pattern (one of M2a′ to M2d′) and the first wiring pattern (one of M2a to M2d).

In some implementations, the first wiring pattern (one of M2a to M2d) may extend toward the peripheral region 122 in the first direction X, and the second wiring pattern (one of M2a′ to M2d′) may extend toward the cell region 121 in the first direction X and may be directly connected to the first wiring pattern (one of M2a to M2d) in the transition region 123 between the cell region 121 and the peripheral region 122.

In some implementations, the cell region 121 may further include a first gate line electrically connected to a first wiring pattern (one of M2a to M2d) to receive one of the first to fourth word line signals WL0 to WL3 from the first wiring pattern (one of M2a to M2d), a first source/drain connected to the bit line BL, a second gate line electrically connected to the first wiring pattern (one of M2a to M2d) to receive one of the first to fourth word line signals WL0 to WL3 from the first wiring pattern (one of M2a to M2d), and a second source/drain connected to the complementary bit line BLB, wherein the first gate line and the first source/drain constitute the first transfer transistor N13, and the second gate line and the second source/drain constitute the second transfer transistor N14.

In some implementations, the cell region 121 may include the first front side wiring layer M1 disposed on the upper surface of the substrate SUB and the second front side wiring layer M2 disposed on the first front side wiring layer M1 and including the first wiring patterns M2a to M2d, and the first and second gate lines may receive a word line signal from the second wiring patterns M2a′ to M2d′ through the first front side wiring layer M1 and the first wiring patterns M2a to M2d.

In some implementations, the plurality of bit cells may be arranged in the cell region 121, and a first bit cell among the plurality of bit cells may include a first transfer transistor (e.g., N13 of FIG. 5) connected to a first word line. A first word line driver (e.g., DRV0 of FIG. 7) connected to the first bit cell may be arranged in the peripheral region 122. The cell region 121 may include a first wiring pattern (one of M2a to M2d) extending toward the peripheral region 122 in the first direction X on a front side wiring layer (e.g., M2) and corresponding to the first word line and a backside wiring pattern (one of BM1a to BM1d) disposed on a backside wiring layer (e.g., BM1) and electrically connected to the first wiring pattern. The peripheral region 122 may include a second wiring pattern (one of M2a′ to M2d′) extending toward the cell region 121 in the first direction X on the front side wiring layer (e.g., M2) and directly connected between the output terminal of the first word line driver and the first wiring pattern. The first transfer transistor N13 may receive a first word line signal (e.g., WL0) from the first word line driver DRV0 through the second wiring pattern (one of M2a′ to M2d′) and the first wiring pattern (one of M2a to M2d).

FIG. 14 is a cross-sectional view of another example of the integrated circuit 120 taken along line X2-X2′ of FIG. 12.

Referring to FIG. 14, the IC 120a corresponds to a modified example of the IC 120 of FIGS. 12 and 13, and the description made above with reference to FIGS. 12 and 13 may also be applied to the example of FIG. 14. The gate insulating layer GI may be disposed on the substrate SUB. The source/drain SD, the source/drain contact CA, and the via VA may be disposed between the substrate SUB and the first front side wiring layer M1. In some implementations, the height of the backside contact BCA′ in the vertical direction Z may be less than the height of the backside contact BCA of FIG. 13 in the vertical direction Z. For example, the height of the backside contact BCA′ may be similar to the height of the substrate SUB.

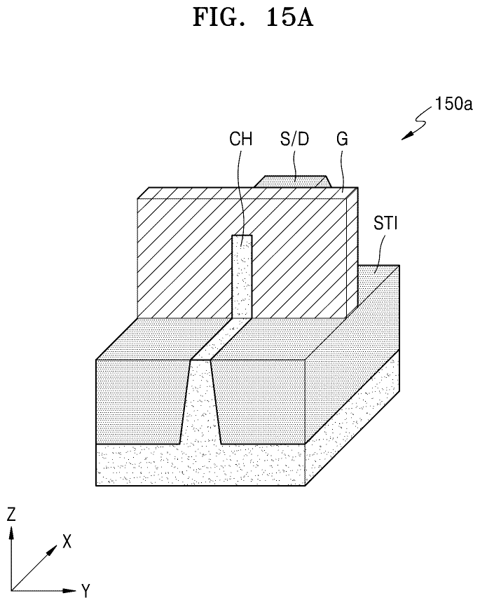

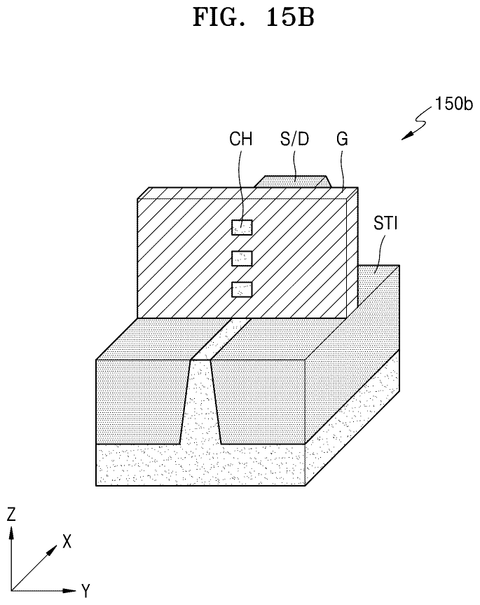

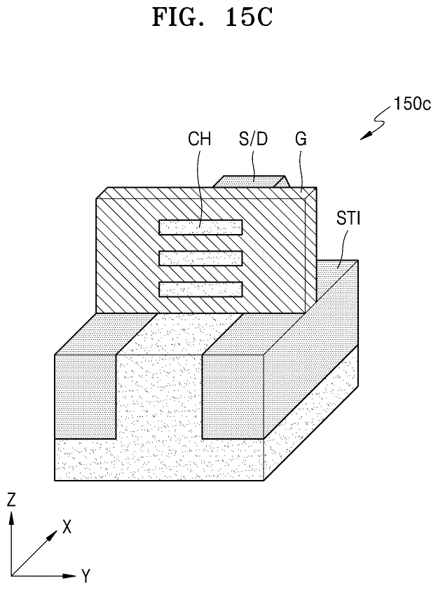

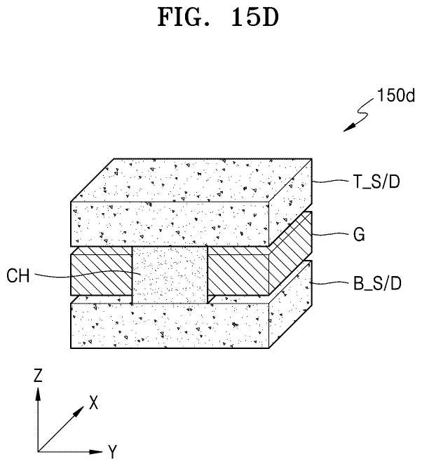

FIGS. 15A to 15D are perspective views of examples of devices that can be included in integrated circuits described herein.

For example, FIG. 15A is a perspective view illustrating a fin FET (FinFET) 150a, FIG. 15B is a perspective view illustrating a GAAFET 150b, FIG. 15C is a perspective view illustrating an MBCFET 150c, and FIG. 15D is a perspective view illustrating a vertical FET (VFET) 150d. For convenience of drawing, FIGS. 15A to 15C show a shape in which one of two source/drain regions S/D is removed, and FIG. 15D shows a cross-section of the VFET 150d cut by a plane which is parallel to the plane formed by the second direction Y and the vertical direction Z and passes through a channel CH of the VFET 150d.

Referring to FIG. 15A, the FinFET 150a may be formed by a fin-shaped active pattern extending in the first direction X between STIs and a gate G extending in the second direction Y. The source/drain regions S/D may be formed at both sides of the gate G, and accordingly, the source/drain regions S/D may be spaced apart from each other in the first direction X. A gate insulating layer (e.g., GI of FIG. 11) may be formed between the channel CH and the gate G. In some implementations, the FinFET 150a may be formed by a plurality of active patterns spaced apart from each other in the second direction Y and the gate G.

Referring to FIG. 15B, the GAAFET 150b may be formed by active patterns, i.e., nanowires, spaced apart from each other in the vertical direction Z and extending in the first direction X and the gate G extending in the second direction Y. The source/drain regions S/D may be formed at both sides of the gate G, and accordingly, the source/drain regions S/D may be spaced apart from each other in the first direction X. A gate insulating layer (e.g., GI of FIG. 11) may be formed between the channel CH and the gate G. The number of nanowires included in the GAAFET 150b is not limited to that shown in FIG. 15B.

Referring to FIG. 15C, the MBCFET 150c may be formed by active patterns, i.e., nanosheets, spaced apart from each other in the vertical direction Z and extending in the first direction X and the gate G extending in the second direction Y. The source/drain regions S/D may be formed at both sides of the gate G, and accordingly, the source/drain regions S/D may be spaced apart from each other in the first direction X. A gate insulating layer (e.g., GI of FIG. 11) may be formed between the channel CH and the gate G. The number of nanosheets included in the MBCFET 150c is not limited to that shown in FIG. 15C.

Referring to FIG. 15D, the VFET 150d may include a top source/drain T_S/D and a bottom source/drain B_S/D spaced apart from each other in the vertical direction Z with the channel CH therebetween. The VFET 150d may include the gate G surrounding the perimeter of the channel CH between the top source/drain T_S/D and the bottom source/drain B_S/D. A gate insulating layer (e.g., GI of FIG. 11) may be formed between the channel CH and the gate G.

Integrated circuits (ICs) as described herein (e.g., with respect to FIGS. 1 to 14) may include a plurality of cells, and each cell may include various transistors illustrated in FIGS. 15A to 15D. However, the transistors are not limited to the structures described with respect to FIGS. 15A to 15D. For example, the IC may include a ForkFET having a structure in which nanosheets for a P-type transistor and nanosheets for an N-type transistor are separated from each other by a dielectric wall such that the N-type transistor is relatively close to the P-type transistor. In addition, the IC may include not only a FET, such as a complementary FET (CFET), a negative capacitance FET (NCFET), or a carbon nanotube FET (CNTFET), but also a bipolar junction transistor.

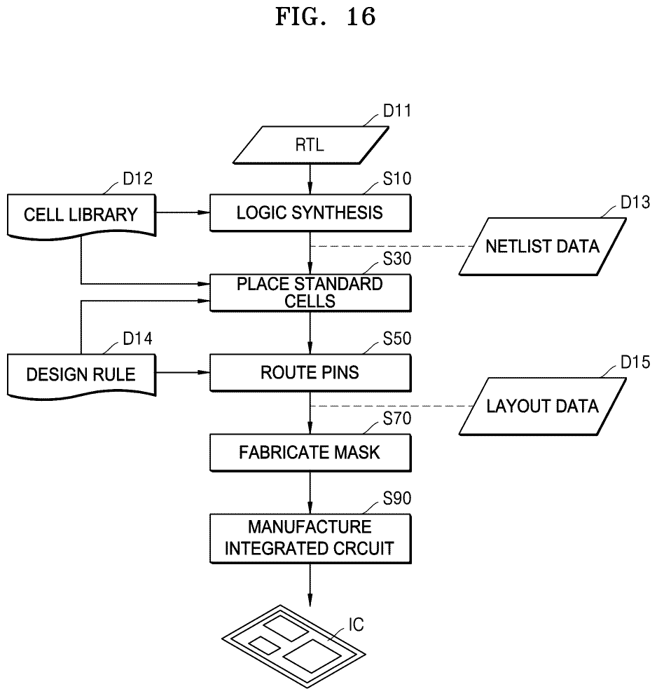

FIG. 16 is a flowchart illustrating an example of a method of manufacturing an IC. Referring to FIG. 16, the method is a method of manufacturing an IC including standard cells and may include a plurality of operations S10, S30, S50, S70, and S90. A cell library (or a standard cell library) D12 may include information about standard cells, e.g., information, such as functions, characteristics, and layouts. In some implementations, the cell library D12 may define not only function cells which generate an output signal from an input signal but also a tap cell, a filler cell, and a dummy cell. For example, the cell library D12 may define filler cells arranged between standard cells having different metal track structures. A design rule D14 may include requirements to which a layout of an IC conforms. For example, the design rule D14 may include requirements for the space between patterns in the same layer, the minimum width of a pattern, the routing direction of a wiring layer, and the like. In some implementations, the design rule D14 may define the minimum separation distance in the same track of the wiring layer.

In operation S10, a logic synthesis operation of generating netlist data D13 from register transfer level (RTL) data D11 may be performed. For example, a semiconductor design tool (e.g., a logic synthesis tool) may perform logic synthesis on the RTL data D11 with reference to the cell library D12, the RTL data D11 being created by a hardware description language (HDL), such as a very high-speed integrated circuit (VHSIC) HDL (VHDL) or Verilog, and generate the netlist data D13 including a bitstream or a netlist. The netlist data D13 may correspond to an input of place and routing (P&R) to be described below.

In operation S30, standard cells may be placed. For example, a semiconductor design tool (e.g., a P&R tool) may place the standard cells used in the netlist data D13, with reference to the cell library D12. In some implementations, the semiconductor design tool may place a standard cell on a row extending in the X-axis direction or the Y-axis direction, and the placed standard cell may receive power from a power rail extending along boundaries of the row.

In operation S50, pins of the standard cells may be routed. For example, the semiconductor design tool may generate interconnections electrically connecting output pins to input pins of the placed standard cells and generate layout data D15 defining the placed standard cells and the generated interconnections. The interconnection may include a via of a via layer and/or patterns of wiring layers. The wiring layers may include a front side wiring layer disposed on the front side of a substrate and a backside wiring layer disposed on the backside of the substrate. The layout data D15 may have, for example, a format, such as generic or geometric data structure information interchange (GDSII), and include geometric information of the cells and the interconnections. The semiconductor design tool may refer to the design rule D14 while routing the pins of the standard cells. The layout data D15 may correspond to an output of P&R. Operation S50 alone or both operations S30 and S50 may be referred to as a method of designing an IC.

According to some implementations of the present disclosure, by applying the above principles and integrated circuit structures, the width of a wiring, e.g., the width of a metal track, included in the front side wiring layer may be increased by using a BSPDN, which supplies a signal and/or power by using the backside wiring layer. In addition, because the degree of routing freedom of the front side wiring layer is improved by using a BSPDN process, when a signal is transferred between a bit cell array and a peripheral circuit, the signal may be transferred through direct connection between wiring patterns in the same layer instead of a detour path through several metal layers and several via layers. For example, because a transfer path for a word line signal is shortened through such direct connection, the length of a word line wiring may be significantly reduced, and accordingly, a wiring resistance may be reduced, thereby improving the performance of a memory device.

As described above, in some implementations, in an IC including a memory device, a wiring resistance may be reduced through direct connection of wirings in the same layer between the bit cell array and the peripheral circuit, thereby improving the operating speed of the IC. In this case, a signal supplied from the peripheral circuit may be supplied to the bit cell array through not a detour path but a direct connection path, thereby improving the PPA of the IC.

In operation S70, an operation of fabricating a mask may be performed. For example, optical proximity correction (OPC) for correcting a distortion phenomenon, such as refraction, caused by characteristics of light in photolithography may be applied to the layout data D15. Patterns on a mask may be defined to form patterns on a plurality of layers based on data to which OPC is applied, and at least one mask (or a photomask) for forming the respective patterns of the plurality of layers may be fabricated. In some implementations, a layout of an IC may be limitedly modified in operation S70, and the limited modification of the IC in operation S70 is post-processing for optimizing the structure of the IC and may be referred to as design polishing.

In operation S90, an operation of manufacturing an IC may be performed. For example, the IC may be manufactured by using the at least one mask, fabricated in operation S70, to pattern a plurality of layers. Front-end-of-line (FEOL) may include, for example, planarizing and cleaning a wafer, forming a trench, forming a well, forming a gate line, and forming a source and a drain. By FEOL, individual devices, e.g., transistors, capacitors, and resistors, may be formed on a substrate. In addition, back-end-of-line (BEOL) may include performing silicidation on gate, source, and drain regions, adding a dielectric, performing planarization, forming a hole, adding a metal layer, forming a via, forming a passivation layer, and the like. By BEOL, the individual devices, e.g., transistors, capacitors, and resistors, may be interconnected. In some implementations middle-of-line (MOL) may be performed between FEOL and BEOL, and contacts may be formed on the individual devices. Next, the IC may be packaged in a semiconductor package and used as a component for various applications.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination. Operations in the drawings may be performed in a different order to that illustrated.

While certain examples have been particularly shown and described, it will be understood that various changes in form and details may be made therein without departing from the spirit and scope of this disclosure.

What is claimed is:

1. An integrated circuit comprising:
a cell region in which a plurality of bit cells are arranged; and
a peripheral region in which a plurality of word line drivers are arranged, the plurality of word line drivers including a first word line driver,
wherein the cell region comprises:
a first gate line extending in a first direction above a substrate,
a first wiring pattern in a front side wiring layer above the first gate line and electrically connected to the first gate line,
a backside contact extending in the substrate in a vertical direction, and
a backside wiring pattern on a backside of the substrate and electrically connected to the first wiring pattern through the backside contact, and
wherein the peripheral region comprises a second wiring pattern in the front side wiring layer and directly connected to the first wiring pattern, wherein the second wiring pattern is configured to transfer a first word line signal, output from the first word line driver, to the first wiring pattern.

2. The integrated circuit of claim 1, wherein the first wiring pattern extends toward the peripheral region in the first direction.

3. The integrated circuit of claim 2, wherein the second wiring pattern extends toward the cell region in the first direction, and is directly connected to the first wiring pattern between the cell region and the peripheral region.

4. The integrated circuit of claim 1, wherein the cell region comprises a first source/drain connected to a first bit line, and
wherein the first gate line and the first source/drain are included in a first transfer transistor of a first bit cell of the plurality of bit cells.

5. The integrated circuit of claim 4, wherein the cell region comprises:
a second gate line electrically connected to the first wiring pattern; and
a second source/drain connected to a first complementary bit line, and
wherein the second gate line and the second source/drain are included in a second transfer transistor of the first bit cell.

6. The integrated circuit of claim 1, wherein the cell region comprises:
a first front side wiring layer including a first pattern extending in a second direction intersecting the first direction, wherein the first pattern is above an upper surface of the substrate,
wherein the front side wiring layer is above the first front side wiring layer, and
wherein the first gate line is configured to receive the first word line signal from the second wiring pattern through the first pattern and the first wiring pattern.

7. The integrated circuit of claim 6, wherein the cell region comprises:
a gate contact between the first gate line and the first front side wiring layer; and
a first via between the first pattern and the first wiring pattern, and
wherein the first gate line is configured to receive the first word line signal from the second wiring pattern through the gate contact, the first pattern, the first via, and the first wiring pattern.

8. The integrated circuit of claim 6, wherein the first front side wiring layer comprises a second pattern extending in the second direction,
wherein the integrated circuit comprises a second via between the second pattern and the first wiring pattern, and
wherein the backside wiring pattern is configured to receive the first word line signal from the second wiring pattern through the backside contact, the second pattern, the second via, and the first wiring pattern.

9. The integrated circuit of claim 1, wherein the first wiring pattern has a first width in a second direction intersecting the first direction, and the second wiring pattern has a second width that is different from the first width in the second direction.

10. The integrated circuit of claim 1, wherein the cell region comprises nanosheets stacked on the substrate in the vertical direction, and wherein each bit cell of the plurality of bit cells comprises a gate-all-around (GAA) transistor.

11. An integrated circuit comprising:
a cell region in which a plurality of bit cells are arranged; and
a peripheral region in which a plurality of word line drivers, respectively connected to the plurality of bit cells, are arranged,
wherein a first bit cell of the plurality of bit cells comprises:
a first transfer transistor connected to a first word line, and
a second transfer transistor connected to the first word line,
wherein the cell region comprises:
a first wiring pattern in a front side wiring layer and including the first word line; and
a backside wiring pattern in a backside wiring layer and electrically connected to the first wiring pattern,
wherein the peripheral region comprises a second wiring pattern in the front side wiring layer and connected between an output terminal of a first word line driver of the plurality of word line drivers and the first wiring pattern,
wherein the second wiring pattern is directly connected to the first wiring pattern, and
wherein each of the first and second transfer transistors is configured to receive a first word line signal from the first word line driver through the second wiring pattern and the first wiring pattern.

12. The integrated circuit of claim 11, wherein the first wiring pattern extends toward the peripheral region in a first direction, and the second wiring pattern extends toward the cell region in the first direction and is directly connected to the first wiring pattern between the cell region and the peripheral region.

13. The integrated circuit of claim 11, wherein the cell region comprises:
a first gate line electrically connected to the first wiring pattern to receive the first word line signal from the first wiring pattern;
a first source/drain connected to a first bit line;
a second gate line electrically connected to the first wiring pattern to receive the first word line signal from the first wiring pattern; and
a second source/drain connected to a first complementary bit line,
wherein the first gate line and the first source/drain are included in the first transfer transistor, and
wherein the second gate line and the second source/drain are included in the second transfer transistor.

14. The integrated circuit of claim 13, wherein the cell region comprises:
a first front side wiring layer above an upper surface of a substrate,
wherein the front side wiring layer is above the first front side wiring layer, and
wherein each of the first and second gate lines is configured to receive the first word line signal from the second wiring pattern through the first front side wiring layer and the first wiring pattern.

15. The integrated circuit of claim 11, wherein the cell region comprises nanosheets stacked on a substrate in a vertical direction, and each bit cell of the plurality of bit cells comprises a gate-all-around (GAA) transistor.

16. An integrated circuit comprising:
a cell region in which a plurality of bit cells are arranged, wherein a first bit cell of the plurality of bit cells includes a first transfer transistor connected to a first word line; and
a peripheral region including a first word line driver connected to the first bit cell,
wherein the cell region comprises:
a first wiring pattern extending toward the peripheral region in a first direction in a front side wiring layer and including the first word line, and
a backside wiring pattern in a backside wiring layer and electrically connected to the first wiring pattern,
wherein the peripheral region comprises a second wiring pattern extending toward the cell region in the first direction in the front side wiring layer and directly connected between an output terminal of the first word line driver and the first wiring pattern, and
wherein the first transfer transistor is configured to receive a first word line signal from the first word line driver through the second wiring pattern and the first wiring pattern.

17. The integrated circuit of claim 16, wherein the cell region comprises:
a first gate line electrically connected to the first wiring pattern to receive the first word line signal from the first wiring pattern; and
a first source/drain connected to a first bit line,
wherein the first gate line and the first source/drain are included in the first transfer transistor.

18. The integrated circuit of claim 17, wherein the cell region comprises:
a first front side wiring layer including a first pattern extending in a second direction intersecting the first direction, above an upper surface of a substrate,
wherein the front side wiring layer is above the first front side wiring layer, and
wherein the first gate line is configured to receive the first word line signal from the second wiring pattern through the first pattern and the first wiring pattern.

19. The integrated circuit of claim 18, wherein the first front side wiring layer comprises a second pattern extending in the second direction, and
wherein the integrated circuit comprises:
a backside contact extending in the substrate in a vertical direction; and
a second via between the second pattern and the first wiring pattern,
wherein the backside wiring pattern is configured to receive the first word line signal from the second wiring pattern through the backside contact, the second pattern, the second via, and the first wiring pattern.

20. The integrated circuit of claim 16, wherein the cell region comprises nanosheets stacked on a substrate in a vertical direction, and each bit cell of the plurality of bit cells comprises a gate-all-around (GAA) transistor.
